(19) United States
(12) Patent Application Publication
(10) Pub. No.: US 2025/0379087 A1
(43) Pub. Date: Dec. 11, 2025

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Ikuo ITAKURA, Fukuoka (JP)

(21) Appl. No.: 19/229,128

(22) Filed: Jun. 5, 2025

(30) Foreign Application Priority Data
Jun. 10, 2024 (JP) 2024-093453

(51) Int. Cl. H01L 21/683

(52) U.S. Cl. CPC H01L 21/6833

(57) ABSTRACT

An electrostatic chuck 10 includes a first portion 101 including a surface 110 on which a wafer W is placed, and a second portion 102 projecting from an outer peripheral end of the first portion 101 further toward an outer peripheral side and being thinner than the first portion 101. A first gas hole 150 is formed in the first portion 101, and a first air-permeable member 400 having air-permeability is arranged inside the first gas hole 150. A second gas hole 160 is formed in the second portion 102, and a second air-permeable member 500 having air-permeability is arranged inside the second gas hole 160. A height dimension of the second air-permeable member 500 is smaller than a height dimension of the first air-permeable member 400.

### CROSS-REFERENCE TO RELATED APPLICATION

This application is based upon and claims the benefit of priority from Japanese Patent Application No. 2024-093453 filed on Jun. 10, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to adsorb and hold a wafer such as a silicon wafer to be processed. The electrostatic chuck includes a dielectric substrate on which an adsorption electrode is provided. When a voltage is applied to the adsorption electrode, an electrostatic force is generated, and the wafer placed on the dielectric substrate is adsorbed and held.

During a process on the wafer, an annular member, which is called a focus ring and the like, is arranged around the wafer. For example, as disclosed in Japanese Patent Laid-Open No. 2004-281680, a flange part for placing such an annular member may be provided on the dielectric substrate. In the dielectric substrate, a portion where the wafer such as a silicon wafer to be processed is placed is also referred to as a “first portion” hereinafter. The above-described flange part disposed on the dielectric substrate is also referred to as a “second portion” hereinafter. The second portion (flange part) projects from an outer peripheral end of the first portion further toward an outer peripheral side, which is a portion thinner than the first portion.

### SUMMARY

A gas hole is formed in the first portion of the dielectric substrate. The gas hole is a through hole for supplying an inert gas toward a space between a placement surface and the wafer. By supplying the inert gas of a predetermined pressure to the space, heat transfer between the wafer and the dielectric substrate is regulated. Due to this, during a process such as etching, a temperature of the wafer can be maintained at an appropriate temperature.

To prevent an electric discharge through the gas hole, an air-permeable member made of an insulator such as alumina is arranged inside the gas hole.

The present inventors have examined forming the gas hole not only in the first portion but also in the second portion, and regulating a temperature of the annular member surrounding the wafer. In this case, similarly to the gas hole in the first portion, the air-permeable member is preferably arranged inside the gas hole in the second portion. However, conventionally, what type of air-permeable member should be arranged in the first portion and the second portion having different thicknesses has not been specifically examined.

The present invention has been made in view of such a problem and aims at providing an electrostatic chuck that can suppress generation of an electric discharge through a gas hole.

To solve the problem described above, the electrostatic chuck according to the present invention includes a first portion including a placement surface on which an object to be adsorbed is placed, and a second portion projecting from an outer peripheral end of the first portion further toward an outer peripheral side and being thinner than the first portion. A first gas hole is formed in the first portion, and a first air-permeable member having air-permeability is arranged inside the first gas hole. A second gas hole is formed in the second portion, and a second air-permeable member having air-permeability is arranged inside the second gas hole. Assuming that a dimension in a direction perpendicular to the placement surface is a height dimension, in this electrostatic chuck, a height dimension of the second air-permeable member is smaller than a height dimension of the first air-permeable member.

In the electrostatic chuck having the above-described configuration, the air-permeable member having an appropriate height dimension corresponding to a length of each hole can be arranged inside each of the first gas hole formed in the first portion and the second gas hole formed in the second portion. For example, by arranging the first air-permeable member so as to occupy substantially the whole first gas hole, and arranging the second air-permeable member so as to occupy substantially the whole second gas hole, generation of an electric discharge through each gas hole can be sufficiently suppressed.

According to the present invention, it is possible to provide an electrostatic chuck that can suppress generation of an electric discharge through a gas hole.

### BRIEF DESCRIPTION OF THE DRAWINGS

FIG. 1 is a cross sectional view schematically illustrating a configuration of an electrostatic chuck according to a first embodiment;

FIGS. 2A and 2B are cross sectional views schematically illustrating configurations of air-permeable members according to the first embodiment;

FIGS. 3A and 3B are diagrams schematically illustrating configurations of the air-permeable members according to the first embodiment;

FIGS. 4A and 4B are cross sectional views schematically illustrating configurations of air-permeable members according to a second embodiment;

FIG. 5 is a diagram schematically illustrating a configuration of an air-permeable member according to a third embodiment;

FIGS. 6A and 6B are cross sectional views schematically illustrating configurations of air-permeable members according to a fourth embodiment; and

FIGS. 7A and 7B are cross sectional views schematically illustrating configurations of air-permeable members according to a fifth embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to adsorb and hold a wafer W set as a process target by an electrostatic force inside a semiconductor manufacturing apparatus such as, for example, an etching apparatus which is not illustrated in the drawing. The wafer W that is an object to be adsorbed is, for example, a silicon wafer. The electrostatic chuck 10 may be used in an apparatus other than the semiconductor manufacturing apparatus.

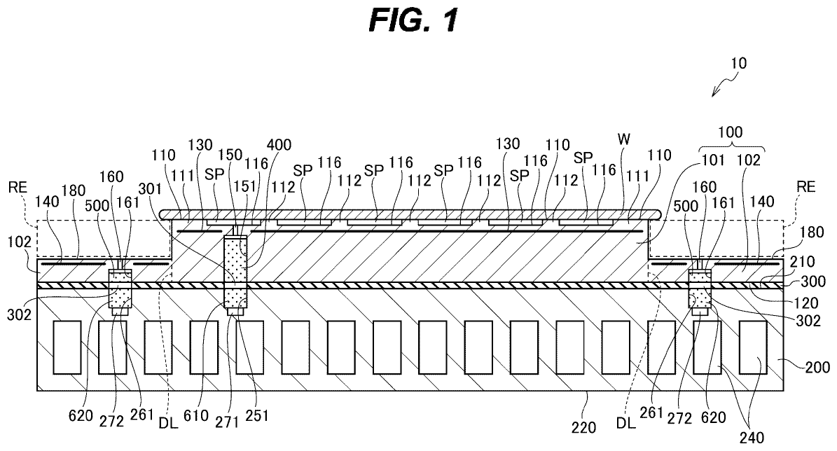

FIG. 1 is a cross sectional view schematically illustrating a configuration of the electrostatic chuck 10 in a state in which the wafer W is adsorbed and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

The dielectric substrate 100 includes a first portion 101 and a second portion 102. The first portion 101 is a substantially columnar (solid cylindrical shape) portion extending from the surface 110 toward a lower side in FIG. 1 to the surface 120. It can be said that the first portion 101 is a portion including the surface 110 as the placement surface in the dielectric substrate 100.

The second portion 102 is an annular portion projecting from an outer peripheral end of the first portion 101 further toward an outer peripheral side, and is a portion also called a “flange part” of the dielectric substrate 100. In FIG. 1, a boundary between the first portion 101 and the second portion 102 is indicated by a dotted line DL. The second portion 102 is thinner than the first portion 101. That is, a dimension of the second portion 102 in a direction perpendicular to the surface 110 (in FIG. 1, an upper and lower direction) is smaller than a dimension of the first portion 101 in the same direction. The surface 120 described above is a surface on a lowermost side of the first portion 101 in FIG. 1, and is also a surface on the lowermost side of the second portion 102. A surface 180 on an uppermost side of the second portion 102 is present at a position lower than the surface 110 in FIG. 1.

When a process on the wafer W is to be performed in the semiconductor manufacturing apparatus, an annular member RE that is called a focus ring and the like is arranged around the wafer W. The surface 180 of the second portion 102 serves as a portion that supports the annular member RE from a lower side. The surface 180 is a surface parallel to the surface 110. The whole annular member RE may be supported by the surface 180 from the lower side as in the example of FIG. 1, or only a part of the annular member RE may be supported thereby.

An adsorption electrode 130 is provided inside the first portion 101 in the dielectric substrate 100. The adsorption electrode 130 is a thin planar layer made of a metallic material such as, for example, tungsten, and is arranged so as to be parallel to the surface 110. As a material of the adsorption electrode 130, molybdenum, platinum, palladium, and the like may be used in addition to tungsten. When a voltage is applied to the adsorption electrode 130 from an outside via a feed line which is not illustrated in the drawing, an electrostatic force is generated between the surface 110 and the wafer W, and according to this, the wafer W is adsorbed and held. As a configuration of the above-described feed line, various configurations in related art can be adopted. The single adsorption electrode 130 may be provided as so-called a “monopolar” electrode as in the present embodiment, but may also include two adsorption electrodes as so-called “bipolar” electrodes.

An internal electrode 140 is provided inside the second portion 102 in the dielectric substrate 100. The internal electrode 140 is a thin planar layer formed of the same material as that of the adsorption electrode 130, and is arranged so as to be parallel to the surface 180. When a voltage is applied to the internal electrode 140 from the outside via the feed line which is not illustrated in the drawing, an electrostatic force is generated between the surface 180 and the annular member RE, and according to this, the annular member RE is adsorbed and held. As a configuration of the above-described feed line connected to the internal electrode 140, various configurations in related art can be adopted. The single internal electrode 140 may be provided as so-called a “monopolar” electrode as in the present embodiment, but may also include two internal electrodes as so-called “bipolar” electrodes.

Inside the dielectric substrate 100, an RF electrode for generating plasma to be adsorbed to the wafer W side may be provided in addition to the above-described adsorption electrode 130 and internal electrode 140. The adsorption electrode 130 and the internal electrode 140 may also be used as the above-described RF electrode.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via the first gas hole 150 which will be described later. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The first gas hole 150 is formed in the first portion 101 of the dielectric substrate 100. The first gas hole 150 is a circular through hole formed so as to extend in a direction perpendicular to the surface 110 serving as the placement surface. An end part on the surface 110 side of the first gas hole 150 is connected to the space SP. The first gas hole 150 is a part of a flow path for supplying the helium gas toward the space SP. The first gas hole 150 includes a plurality of first gas holes 150 which are formed in the first portion 101, but FIG. 1 illustrates only one of the first gas holes 150.

A portion on the surface 120 side of the first gas hole 150 has an expanded diameter as compared with that of a portion on the surface 110 side. The portion having such an expanded diameter is also referred to as an “expanded-diameter section 151” hereinafter. A first air-permeable member 400 is arranged inside the expanded-diameter section 151. The first air-permeable member 400 is a substantially columnar member formed of an insulating material, and has air-permeability as described later. In the present embodiment, alumina is used as a material of the first air-permeable member 400. The first air-permeable member 400 is provided to prevent an electric discharge (dielectric breakdown) from the wafer W to the base plate 200 through the first gas hole 150. A specific configuration of the first air-permeable member 400 will be described later.

A second gas hole 160 is formed in the second portion 102 of the dielectric substrate 100. The second gas hole 160 is a circular through hole formed so as to extend in a direction perpendicular to the surface 110 and the surface 180. An end part on the surface 180 side of the second gas hole 160 is opened on the surface 180. The second gas hole 160 is a part of a flow path for supplying the helium gas toward a gap which is not illustrated in the drawing between the surface 180 and the annular member RE. When the helium gas is caused to be present between the surface 180 and the annular member RE, a thermal resistance between the surface 180 and the annular member RE is regulated, and according to this, a temperature of the annular member RE is maintained at an appropriate temperature. The second gas hole 160 includes a plurality of second gas holes 160 which are formed in the second portion 102 so as to be arranged in an annular shape in top view, but FIG. 1 illustrates only two of the second gas holes 160. The gas supplied through the second gas hole 160 may be a gas of a type different from a gas supplied through the first gas hole 150.

A portion on the surface 120 side of the second gas hole 160 has an expanded diameter as compared with that of a portion on the surface 180 side. The portion having such an expanded diameter is also referred to as an “expanded-diameter section 161” hereinafter. A second air-permeable member 500 is arranged inside the expanded-diameter section 161. The second air-permeable member 500 is a substantially columnar member formed of an insulating material, and has air-permeability as described later. In the present embodiment, alumina is used as a material of the second air-permeable member 500. The second air-permeable member 500 is provided to prevent an electric discharge to the base plate 200 through the second gas hole 160. A specific configuration of the second air-permeable member 500 will be described later.

The base plate 200 is a substantially disk-shaped member which supports the dielectric substrate 100. The base plate 200 is made of, for example, a metallic material such as aluminum. A surface 210 on the upper side in FIG. 1 in the base plate 200 serves as a “surface to be joined” which is joined to the dielectric substrate 100 via the joining layer 300. An outer shape of the surface 210 in top view is substantially the same as an outer shape of the second portion 102 in top view.

The joining layer 300 is a layer provided between the dielectric substrate 100 and the base plate 200 to join those components. The joining layer 300 is obtained by causing an adhesive made of an insulating material to be cured. According to the present embodiment, a silicone adhesive is used as the above-described adhesive. It is noted however that the joining layer 300 may be obtained by causing an adhesive made of other types to be cured. In any case, in order that a thermal resistance between the dielectric substrate 100 and the base plate 200 is reduced, a material with a highest possible thermal conductivity is preferably used as the material of the joining layer 300.

An insulating film may be formed on a surface of the base plate 200. As the insulating film, for example, an alumina film formed by thermal spraying can be used. When the surface of the base plate 200 is covered by the insulating film, it is possible to increase an insulation withstand (breakdown) voltage of the base plate 200.

A coolant flow path 240 through which a coolant flows is formed inside the base plate 200. When the process such as etching is performed in the semiconductor manufacturing apparatus, the coolant is supplied from the outside to the coolant flow path 240, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 240 are performed via openings which are not illustrated in the drawing and which are formed in a surface 220 opposite to the surface 210 in the base plate 200. The coolant flow path 240 is formed so as to pass through not only a range overlapped with the first portion 101 in top view but also a range overlapped with the second portion 102. Due to this, not only the wafer W but also the annular member RE is cooled by the coolant passing through the coolant flow path 240.

In the surface 210 of the base plate 200, a gas hole 251 is formed at each position overlapped with the expanded-diameter section 151 in top view. A shape of the gas hole 251 in top view is a circular shape that is the same as a shape of the expanded-diameter section 151 in top view. The gas hole 251 is formed so as to extend from the surface 210 in a direction perpendicular to the surface 210 to a predetermined depth.

An opening 301 is formed at a position between the expanded-diameter section 151 and the gas hole 251 in the joining layer 300. An end part on the surface 210 side of the gas hole 251 communicates with the expanded-diameter section 151 of the first gas hole 150 via the opening 301. An end part on the opposite side of the gas hole 251 communicates with a distribution flow path 271 formed inside the base plate 200.

The distribution flow path 271 is a flow path that is formed so as to distribute the helium gas supplied from the outside to each of a plurality of gas holes 251. The distribution flow path 271 is routed along a path passing through immediately below all of the gas holes 251. A plurality of distribution flow paths 271 may be formed, and supply of the helium gas to the gas hole 251 may be separately performed by a plurality of systems. With such a configuration, for example, a pressure of the helium gas supplied to the gas hole 251 on a center side can be caused to be different from a pressure of the helium gas supplied to the gas hole 251 on the outer peripheral side.

An air-permeable member 610 is arranged inside the gas hole 251. The air-permeable member 610 is a substantially columnar member, and has air-permeability. In the present embodiment, porous alumina is used as the air-permeable member 610. The air-permeable member 610 may be a member in which a plurality of air (ventilation) holes linearly extending from an end part on one side to an end part on another side are formed, or may be a member in which a mesh-shaped flow path is formed.

In the surface 210 of the base plate 200, a gas hole 261 is formed at each position overlapped with the expanded-diameter section 161 in top view. A shape of the gas hole 261 in top view is a circular shape that is the same as a shape of the expanded-diameter section 161 in top view. The gas hole 261 is formed so as to extend from the surface 210 in a direction perpendicular to the surface 210 to a predetermined depth.

An opening 302 is formed at a position between the expanded-diameter section 161 and the gas hole 261 in the joining layer 300. An end part on the surface 210 side of the gas hole 261 communicates with the expanded-diameter section 161 of the second gas hole 160 via the opening 302. An end part on the opposite side of the gas hole 261 communicates with a distribution flow path 272 formed inside the base plate 200.

The distribution flow path 272 is a flow path that is formed so as to distribute the helium gas supplied from the outside to each of a plurality of gas holes 261. The distribution flow path 272 is routed along a path passing through immediately below all of the gas holes 261. A plurality of distribution flow paths 272 may be formed, and supply of the helium gas to the gas hole 261 may be separately performed by a plurality of systems. With such a configuration, for example, a pressure of the helium gas supplied to the gas hole 261 on the center side can be caused to be different from a pressure of the helium gas supplied to the gas hole 261 on the outer peripheral side. The distribution flow path 272 may be connected to the distribution flow path 271.

An air-permeable member 620 is arranged inside the gas hole 261. The air-permeable member 620 is a substantially columnar member, and has air-permeability. In the present embodiment, porous alumina is used as the air-permeable member 620. The air-permeable member 620 may be a member in which a plurality of air holes linearly extending from an end part on one side to an end part on another side are formed, or may be a member in which a mesh-shaped flow path is formed.

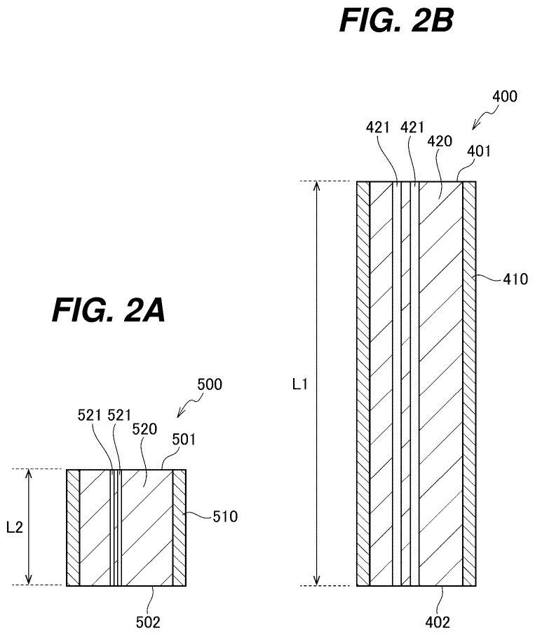

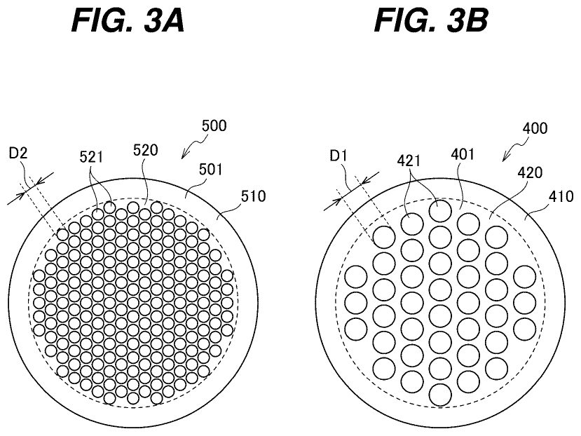

Configurations of the first air-permeable member 400 and the second air-permeable member 500 will be described below. FIG. 2A schematically illustrates a cross section in a case of cutting the columnar second air-permeable member 500 along a surface passing through a center axis thereof. FIG. 2B schematically illustrates a cross section in a case of cutting the columnar first air-permeable member 400 along a surface passing through a center axis thereof. FIG. 3A illustrates the configuration of the second air-permeable member 500 in top view. FIG. 3B illustrates the configuration of the first air-permeable member 400 in top view.

First, the first air-permeable member 400 will be described. The first air-permeable member 400 includes an outer peripheral part 410 and a center part 420. The outer peripheral part 410 is a cylindrical (hollow cylindrical shape) portion on an outermost peripheral side of the first air-permeable member 400. The outer peripheral part 410 is configured as dense alumina as a whole, and does not have air-permeability.

The center part 420 is a substantially columnar portion on an inner side of the outer peripheral part 410. A plurality of first air holes 421 are formed in the center part 420. The first air hole 421 is a circular through hole that is formed so as to linearly extend from an end face 401 on the upper side in FIG. 2 to an end face 402 on the lower side in the first air-permeable member 400. A direction in which each of the first air holes 421 extends is a direction perpendicular to the end face 401 (that is, a direction along a center axis of the first air-permeable member 400). As illustrated in FIG. 3B, the plurality of first air holes 421 are formed, and they are arranged so as to be uniformly distributed at the end face 401. However, only two of the first air holes 421 are illustrated in FIG. 2B. The helium gas supplied from the gas hole 251 of the base plate 200 passes through each of the first air holes 421 to flow toward the end face 401. As described herein, the center part 420 serves as a portion having air-permeability.

In FIG. 2B, hatching is different between the outer peripheral part 410 and the center part 420, but actually, there is no difference between materials constituting the outer peripheral part 410 and the center part 420. Only a difference between the outer peripheral part 410 and the center part 420 is whether the plurality of first air holes 421 are formed.

The first air holes 421 may be formed so as to be uniformly distributed at the end face 401 of the center part 420, but a region in which the first air hole 421 is not present may be provided at a part of the end face 401. For example, it is possible not to provide the first air hole 421 in a region overlapped with a portion on a downstream side of the first gas hole 150 (a small-diameter portion serving as a final outlet of the gas) in top view. With such a configuration, an electric discharge through a path via the first gas hole 150 can be suppressed.

Next, the second air-permeable member 500 will be described. The second air-permeable member 500 includes an outer peripheral part 510 and a center part 520. The outer peripheral part 510 is a cylindrical (hollow cylindrical shape) portion on the outermost peripheral side of the second air-permeable member 500. The outer peripheral part 510 is configured as dense alumina as a whole, and does not have air-permeability.

The center part 520 is a substantially columnar portion on an inner side of the outer peripheral part 510. A plurality of second air holes 521 are formed in the center part 520. The second air hole 521 is a circular through hole that is formed so as to linearly extend from an end face 501 on the upper side in FIG. 2 to an end face 502 on the lower side in the second air-permeable member 500. A direction in which each of the second air holes 521 extends is a direction perpendicular to the end face 501 (that is, a direction along a center axis of the second air-permeable member 500). As illustrated in FIG. 3A, the plurality of second air holes 521 are formed, and they are arranged so as to be uniformly distributed at the end face 501. However, only two of the second air holes 521 are illustrated in FIG. 2A. The helium gas supplied from the gas hole 261 of the base plate 200 passes through each of the second air holes 521 to flow toward the end face 501. As described herein, the center part 520 serves as a portion having air-permeability.

In FIG. 2A, hatching is different between the outer peripheral part 510 and the center part 520, but actually, there is no difference between materials constituting the outer peripheral part 510 and the center part 520. Only a difference between the outer peripheral part 510 and the center part 520 is whether the plurality of second air holes 521 are formed.

The second air holes 521 may be formed so as to be uniformly distributed at the end face 501 of the center part 520, but a region in which the second air hole 521 is not present may be provided at a part of the end face 501. For example, it is possible not to provide the second air hole 521 in a region overlapped with a portion on the downstream side of the second gas hole 160 (a small-diameter portion serving as a final outlet of the gas) in top view. With such a configuration, an electric discharge through a path via the second gas hole 160 can be suppressed.

The first air-permeable member 400 and the second air-permeable member 500 having the configurations as described above can be manufactured by using extrusion molding, for example.

As illustrated in FIG. 2, a height dimension L2 of the second air-permeable member 500 is smaller than a height dimension L1 of the first air-permeable member 400. The “height dimension” means a dimension in a direction perpendicular to the surface 110 as the placement surface, which is a dimension in an upper and lower direction in FIG. 1 and FIG. 2.

In place of such a configuration, for example, height dimensions thereof may be caused to be the same. Specifically, the height dimension L1 of the first air-permeable member 400 may be shortened so as to be the same as the height dimension L2 of the second air-permeable member 500 to achieve commonality of components.

However, with such a configuration, the height dimension L1 of the first air-permeable member 400 becomes too short as compared with a total length of the first gas hole 150, so that there is a possibility that generation of an electric discharge via the first gas hole 150 cannot be sufficiently suppressed.

Thus, in the present embodiment, the height dimension L1 of the first air-permeable member 400 is caused to be longer than the height dimension L2 of the second air-permeable member 500. That is, an air-permeable member having an appropriate height dimension corresponding to a length of each hole is arranged in each of the first gas hole 150 and the second gas hole 160. By arranging the first air-permeable member 400 so as to occupy substantially the whole first gas hole 150, and arranging the second air-permeable member 500 so as to occupy substantially the whole second gas hole 160, generation of an electric discharge through the first gas hole 150 or the second gas hole 160 can be sufficiently suppressed.

The height dimension L1 of the first air-permeable member 400 is preferably larger than a thickness of the second portion 102 of the dielectric substrate 100.

As described above, in the first air-permeable member 400, the plurality of first air holes 421 extending from the end part on one side thereof (end face 401) to the end part on the other side (end face 402) are formed. Also in the second air-permeable member 500, the plurality of second air holes 521 extending from the end part on one side thereof (end face 501) to the end part on the other side (end face 502) are formed. With such a configuration, an electric discharge is prevented while securing air-permeability. In the present embodiment, a flow path length of the first air hole 421 is the same as the height dimension L1 of the first air-permeable member 400. A flow path length of the second air hole 521 is the same as the height dimension L2 of the second air-permeable member 500.

The second air-permeable member 500 is to be arranged in the thin second portion 102, so that the height dimension L2 of the second air-permeable member 500 is small. Thus, there is a concern that an electric discharge through the second gas hole 160 cannot be sufficiently prevented. Thus, in the present embodiment, as illustrated in FIG. 3, an inner diameter D2 of the second air hole 521 is set to be smaller than an inner diameter D1 of the first air hole 421. By reducing the inner diameter D2 of the second air hole 521, voltage withstand performance of the second air-permeable member 500 having the small height dimension L2 can be improved to be closer to voltage withstand performance of the first air-permeable member 400.

In a case in which the inner diameter D2 of the second air hole 521 is reduced as described above, there is a possibility that air-permeability of the second air-permeable member 500 is excessively lowered, and the helium gas at a sufficient flow rate cannot be supplied to the annular member RE side. Thus, in the present embodiment, a total number of the second air holes 521 formed in the one second air-permeable member 500 is caused to be larger than a total number of the first air holes 421 formed in the one first air-permeable member 400. According to this, air-permeability of the second air-permeable member 500 can be sufficiently secured.

A second embodiment will be described. Hereinafter, an aspect different from the first embodiment will be mainly described, and descriptions on an aspect common to the first embodiment are not repeated as appropriate.

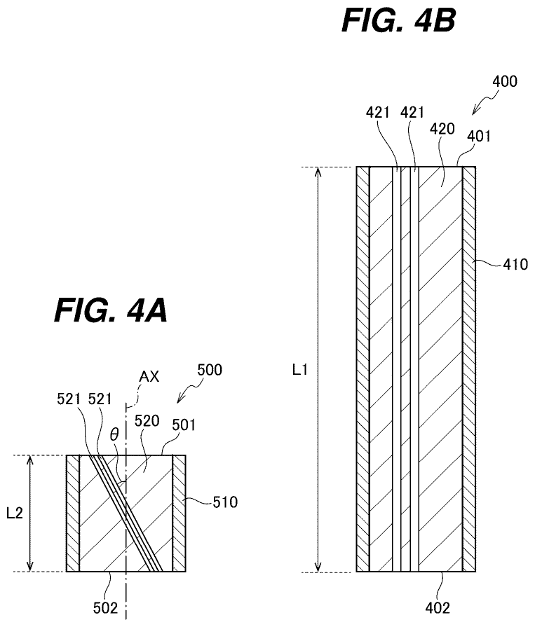

The present embodiment is different from the first embodiment in the configuration of the second air-permeable member 500. FIG. 4A illustrates a configuration of the second air-permeable member 500 according to the present embodiment as a schematic cross sectional view similarly to FIG. 2A. FIG. 4B illustrates a configuration of the first air-permeable member 400 according to the present embodiment as a reference, but this configuration is the same as the configuration in the first embodiment in FIG. 2B.

FIG. 4A illustrates a center axis AX of the second air-permeable member 500. It can be said that the center axis AX is an axis indicating a normal direction of the surface 110 as the placement surface. In the FIG. 4A, “θ” represents an inclination angle of the second air hole 521 with respect to the above-described normal direction.

In the second air-permeable member 500 according to the present embodiment, the second air hole 521 extends obliquely so that the inclination angle of the second air hole 521 with respect to the above-described normal direction is larger than an inclination angle of the first air hole 421 with respect to the above-described normal direction (0 degrees in the example of FIG. 4B). As a result, the flow path length of the second air hole 521 is longer than the height dimension L2 of the second air-permeable member 500, so that the voltage withstand performance of the second air-permeable member 500 is further improved as compared with the first embodiment.

As the second air-permeable member 500, for example, a porous member in which the plurality of second air holes 521 are formed may be prepared in advance, and a columnar member may be formed by being obliquely cut out from the porous member. That is, the porous member may be cut out to have a columnar shape in which the center axis is inclined with respect to the second air hole 521. Thereafter, the outer peripheral part 510 may be provided so as to cover an outer circumference of the member (that is, the center part 520). In this case, the center part 520 and the outer peripheral part 510 may be formed in advance as separate members, and joined to each other by bonding, for example. Both members may be integrated with each other by sintering.

A third embodiment will be described. Hereinafter, an aspect different from the first embodiment will be mainly described, and descriptions on an aspect common to the first embodiment are not repeated as appropriate.

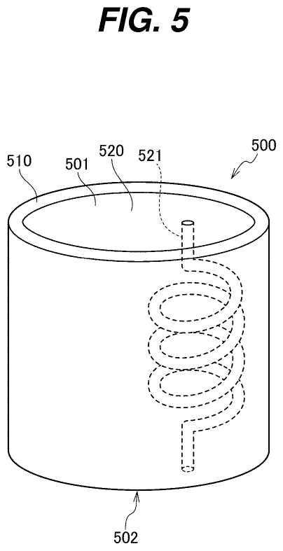

The present embodiment is also different from the first embodiment in the configuration of the second air-permeable member 500. FIG. 5 illustrates a schematic perspective view of the configuration of the second air-permeable member 500 according to the present embodiment.

In the second air-permeable member 500 according to the present embodiment, the second air hole 521 does not linearly extend, and is formed so as to extend spirally (in a spiral shape) from the end face 501 to the end face 502. On the other hand, the first air hole 421 which is not illustrated in the drawing is formed so as to linearly extend similarly to the first embodiment in FIG. 2 and the like. A plurality of spiral-shaped second air holes 521 are formed in the one second air-permeable member 500, but only one of the second air holes 521 is illustrated in FIG. 5.

In the present embodiment, the flow path length of the spiral-shaped second air hole 521 is longer than the height dimension L2 of the second air-permeable member 500. According to this, the voltage withstand performance of the second air-permeable member 500 is further improved as compared with the first embodiment.

The second air-permeable member 500 having the configuration as in FIG. 5 can be manufactured, for example, by putting a spiral-shaped core in a compact before sintering, and burning down the core at the time of sintering. The second air-permeable member 500 may be manufactured by using a 3D printer.

A fourth embodiment will be described. Hereinafter, an aspect different from the first embodiment will be mainly described, and descriptions on an aspect common to the first embodiment are not repeated as appropriate.

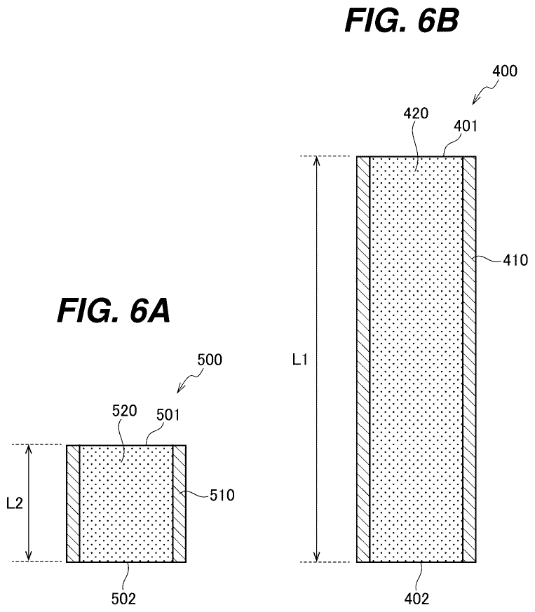

The present embodiment is different from the first embodiment in the configurations of the first air-permeable member 400 and the second air-permeable member 500. FIG. 6A illustrates a configuration of the second air-permeable member 500 according to the present embodiment as a schematic cross sectional view similarly to FIG. 2A. FIG. 6B illustrates a configuration of the first air-permeable member 400 according to the present embodiment as a schematic cross sectional view similarly to FIG. 2B.

In the second air-permeable member 500 in the present embodiment, the whole center part 520 is configured as a porous member in which a mesh-shaped flow path is formed. Similarly, in the first air-permeable member 400 in the present embodiment, the whole center part 420 is configured as a porous member in which a mesh-shaped flow path is formed. However, a porosity of the center part 520 (that is, a porosity of the second air-permeable member 500) is smaller than a porosity of the center part 420 (that is, a porosity of the first air-permeable member 400). With such a configuration, the voltage withstand performance of the second air-permeable member 500 can be improved. The mesh-shaped flow path may be formed only in a part of the second air-permeable member 500 (center part 520), or may be formed in the whole second air-permeable member 500. Similarly, the mesh-shaped flow path may be formed only in a part of the first air-permeable member 400 (center part 420), or may be formed in the whole first air-permeable member 400.

A fifth embodiment will be described. Hereinafter, an aspect different from the first embodiment will be mainly described, and descriptions on an aspect common to the first embodiment are not repeated as appropriate.

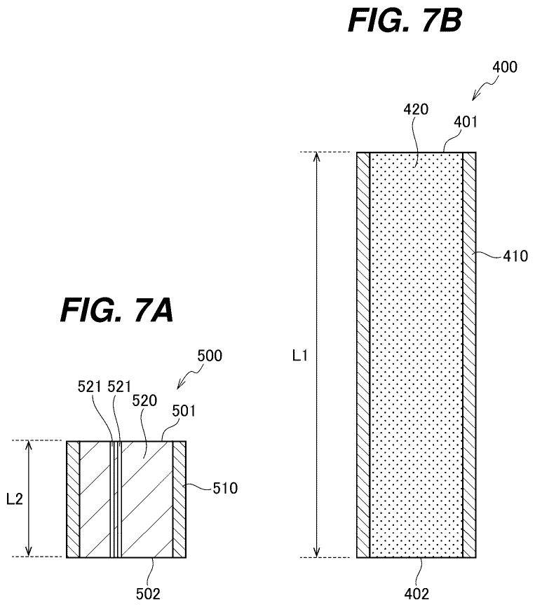

FIG. 7A illustrates a configuration of the second air-permeable member 500 according to the present embodiment. The configuration of the second air-permeable member 500 according to the present embodiment is the same as the configuration of the second air-permeable member 500 according to the first embodiment (FIG. 2A). FIG. 7B illustrates a configuration of the first air-permeable member 400 according to the present embodiment. The configuration of the first air-permeable member 400 according to the present embodiment is the same as the configuration of the first air-permeable member 400 according to the fourth embodiment (FIG. 6A).

That is, in the present embodiment, the first air-permeable member 400 is configured as a member in which the mesh-shaped flow path is formed, and the second air-permeable member 500 is configured as a member in which the plurality of second air holes 521 extending from the end part on one side to the end part on the other side are formed. With such a configuration too, the voltage withstand performance of the second air-permeable member 500 can be improved, and an effect similar to that described in the first embodiment and the like can be exhibited.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a first portion including a placement surface on which an object to be adsorbed is placed; and
a second portion projecting from an outer peripheral end of the first portion further toward an outer peripheral side and being thinner than the first portion, wherein
a first gas hole is formed in the first portion,
a first air-permeable member having air-permeability is arranged inside the first gas hole,
a second gas hole is formed in the second portion,
a second air-permeable member having air-permeability is arranged inside the second gas hole, and
assuming that the dimension in a direction perpendicular to the placement surface is defined as a height dimension,
a height dimension of the second air-permeable member is smaller than a height dimension of the first air-permeable member.

2. The electrostatic chuck according to claim 1, wherein
a plurality of first air holes extending from an end part on one side to an end part on another side are formed in the first air-permeable member, and
a plurality of second air holes extending from an end part on one side to an end part on another side are formed in the second air-permeable member.

3. The electrostatic chuck according to claim 2, wherein an inner diameter of the second air hole is smaller than an inner diameter of the first air hole.

4. The electrostatic chuck according to claim 3, wherein a total number of the second air holes formed in the one second air-permeable member is larger than a total number of the first air holes formed in the one first air-permeable member.

5. The electrostatic chuck according to claim 2, wherein an inclination angle of the second air hole with respect to a normal direction of the placement surface is larger than an inclination angle of the first air hole with respect to the same direction.

6. The electrostatic chuck according to claim 2, wherein the first air hole extends linearly, and the second air hole extends spirally.

7. The electrostatic chuck according to claim 1, wherein
each of the first air-permeable member and the second air-permeable member is a member in which a mesh-shaped flow path is formed, and
a porosity of the second air-permeable member is smaller than a porosity of the first air-permeable member.

8. The electrostatic chuck according to claim 1, wherein
the first air-permeable member is a member in which a mesh-shaped flow path is formed, and
the second air-permeable member is a member in which a plurality of air holes extending from an end part on one side to an end part on another side are formed.
